(19) United States
(12) Patent Application Publication
(10) Pub. No.: US 2005/0150759 A1
(43) Pub. Date: Jul. 14, 2005

(54) Powder and coating formation method and apparatus

(76) Inventor: Isaac Tsz Hong Chang, Birmingham (GB)

Correspondence Address: ANDRUS, SCEALES, STARKE & SAWALL, LLP, 100 EAST WISCONSIN AVENUE, SUITE 1100, MILWAUKEE, WI, 53202, US

(21) Appl. No.: 10/508,913

(22) PCT Filed: Mar. 24, 2003
(86) PCT No.: PCT/GB03/01250

(30) Foreign Application Priority Data
Mar. 23, 2002 (GB) 0206906.0
Jul. 17, 2002 (GB) 02167712.0

(51) Int. Cl. C23C 14/32

(52) U.S. Cl. 204/192.38; 204/298.41

(57) ABSTRACT

The invention relates to a process for the production of submicron particles (26) and comprises the steps of: (i) placing first and second electrodes, (6, 10) in a volume of coolant, such that the electrodes (6, 10) are mutually spaced, (ii) passing an electrical current across the electrodes to generate an electrical arc (24) between them, (iii) maintaining a stable arc (24) by controlling the relative spacing between the two electrodes (6, 10) to melt or evaporate and separate material from at least one of the electrodes (6, 10) such that droplets of said material are formed, and (iv) quenching said droplets to form said submicron particles (26) of the material in the coolant. The invention also relates to a powder coating method and to an apparatus for performing the methods of the invention.

The present invention relates to a method and apparatus for the production of submicron powders and for deposition of coatings on a substrate.

There is an increasing demand for fine powders with particle size below 1 μm for a range of applications including catalysis, low temperature sintering, solid rocket fuel, cold-gas spray coating, powder injection moulding, magnetic targetted carriers, metallic paint and conducting paste. A powder with a particle size below 1 μm has extremely high reactivity and can be accelerated to the same velocity as that of a transporting gas medium. These unique properties allow such powders to enhance (i) the rate of heat-release during burning for solid rocket fuel, (ii) spray coating at low temperature, (iii) magnetic properties, (iv) reactivity and (iv) sintering kinetics at lower temperatures for the densification of powder materials.

Conventional industrial production of metal powders by such processes as reduction, decomposition and gas/water atomisation produces a wide size distribution from 2-500 μm and a range of particle morphology from spherical to irregular. The weight fraction of particles with size below 2 μm is usually below 5%. These conventional industrial processes therefore have a very low yield for fine powder particles and therefore are not economically viable for the large scale production of fine powder particles.

Alternative methods (e.g. inert gas condensation (IGC), chemical vapour condensation (CVC), mechanochemical processing, plasma atomisation and sonochemical synthesis) have been developed and have demonstrated successfully the production of nanosized metal powders. The IGC method involves evaporation of the material into its vapour state inside a vacuum chamber using either resistive heating, electron beam heating or a sputtering system. Above the evaporation source is a cold finger, and a region of supersaturated metal vapour between the cold finger and the evaporation source, which nucleates small ‘liquid-like’ particles. The gas convection between the hot evaporation source and the cold finger transports the ‘liquid-like’ particles away from the evaporation source region. These particles then solidify onto the cold finger as ultrafine solid particles. Another variant of the IGC method involves the use of chemical vapour such as CVC rather than the physical vapour. All IGC-based methods require expensive vacuum systems or a chemical reaction chamber. Furthermore, such methods are currently limited to small batch production.

A non-vacuum based method (plasma atomisation) involves the melting and evaporation of a thin wire of material by a plasma torch. The vapour is then condensed by the inert gas around the plasma. Although the production yield of this method is high, the capital cost of the plasma torch and the necessary ancillary cooling systems can be very expensive. Furthermore, this method also requires an expensive powder handling system to protect the fine powder particles from exposure to air.

A mechanochemical processing method involves a reaction between an oxide powder and a reducing additive induced by high-energy ball milling. The method leads to the formation of by-products, which, need to be removed by a subsequent purification process. Consequently, the mechanochemical processing method is expensive and gives a low yield of submicron sized powder.

The sonochemical synthesis of nanosized powder is based on the use of the acoustic cavitation phenomenon to decompose volatile solvent precursors to ultrafine solid powder particles. The sonochemical synthesis method is less widely applicable due to the need for volatile solvent precursors. In addition, several purification stages are required to extract the ultrafine powder particles.

Coatings, especially those having a thickness greater than 1 μm, are usually deposited using thermal spraying techniques. However, such coatings usually contain a significant level of porosity, which can lead to inferior surface properties.

It is an object of the present invention to provide an improved process for the production of submicron particle powders and for depositing a coating on a substrate and an apparatus for carrying out the processes which obviate or mitigate one or more of the aforementioned disadvantages.

According to a first aspect of the present invention, there is provided a process for the production of submicron particles comprising the steps of:—
(i) placing first and second electrodes in a volume of coolant, the electrodes being mutually spaced,
(ii) passing an electrical current across the electrodes whereby to generate an electrical arc therebetween,
(iii) maintaining a stable arc by controlling the relative spacing between the two electrodes to melt or evaporate and separate material from at least one of the electrodes such that droplets of said material are formed, and
(iv) quenching said droplets to form said submicron particles of the material in the coolant.

The current applied in step (ii) may be alternating or direct.

In a preferred embodiment, the electrodes are initially in contact when the electrical current is passed through them, the arc of step (ii) being created by moving them apart.

Suitable electrode materials (and hence the particles formed) include metals (eg. iron, tungsten, aluminium, titanium, magnesium and nickel), metal alloys (eg. low carbon steel, cast iron, TiAl, Ti-6Al4V, stainless steel, tool steel, Fe—Ni—Co—Cr—Mo, Al—Cu—Fe—Mg—Si, Ni—Co—Cr—Fe—W, Cu—Ni, Cu—Sn, Mg—Al—Mn—Si and Co—Cr—Ni—Fe—Mo—W), graphite and other compounds, eg. carbides (such as SiC, WC), nitrides (such as TiN, AlN and Si₃N₄), oxides (such as PbTiO₃, TiO₂ and SnO₂), noble metals (Au, Pt, Ag etc.), amorphous compositions (eg. Au—Ge, Co—Fe—B—Si—B—Mo, Zr—Al—Ni—Cu) and metal hydrides (such as MgH₂). The electrodes may be bilayer or multilayer. For examples, bilayer electrodes can be made up of an outer layer of graphite (or gold) and an inner core of Fe for the production of nanosized particles comprising of a shell of graphite (or gold) and a core of iron or alternatively an outer layer of tin (or copper) and an inner core of aluminium (or iron) for the production of nanosized particles comprising tin (or copper) coated aluminium (or iron). These coated nanoparticles can have applications in magnetic targetted carriers and liquid phase sintering for powder metallurgical components. In addition, the multilayer electrodes can be made up of alternative layers of Fe and Cu for the production of nanosized particle of multilayers of Fe and Cu. The multilayer nanosized powders can have application in giant magnetoresistance devices.

The coolant is preferably maintained at a temperature of less than 200 K, and more preferably less than 100 K. Most preferably, the coolant is liquid nitrogen (77 K) or liquid argon (87K). For certain metals such as Ti, the preferred coolant is liquid argon.

The coolant may be inert (as in the case of liquid nitrogen). However a quantity of reactant may be mixed with an essentially inert coolant such that the material melted/evaporated in step (iii) reacts with the reactant prior to being quenched in step (iv). In a preferred embodiment a quantity of solvent is introduced into the coolant after step (iv) so as to protect the submicron particles after the removal of the coolant for collection. Furthermore, a small quantity of surfactant can be introduced into the coolant prior to step (iii) or after the solvent addition to prevent agglomeration of the submicron particles. The isolated submicron particles can be treated further with chemicals to make them active to specific chemical molecules.

During step (iii), a flow of coolant may be introduced into the spacing between the electrodes and used to displace droplets formed out of the hot zone of the arc and to top up the coolant to maintain a constant level of coolant.

Preferably step (iii) is achieved by moving, preferably continuously, one of the electrodes relative to the other as material is melted/evaporated. For example, one of the electrodes may be replaced by a non-consuming electrode such as tungsten to provide the stable arc and electrode comprising the materials to be evaporated and condensed into submicron particles can be moved (e.g. lowered) into the arc at a controllable rate.

During step (iii), relative rotation may be induced between the electrodes (eg. by rotating one of the electrodes) whereby to promote separation of the material from the electrode.

Said process may be a batch process, the particles being recovered after removal of the coolant (evaporation in the case of liquid nitrogen). It will be understood that the particles are protected from contact by air whilst contained within the coolant.

Alternatively, the process may be continuous, the method including a step of continuously passing coolant over the electrodes. In a particularly preferred embodiment, the particles are separated from the coolant after passing over the electrodes and the coolant is recycled back over the electrodes in a continuous circuit.

According to a second aspect of the present invention, there is provided a process for depositing a coating on a substrate comprising the steps of:—
(i) placing first and second electrodes in a volume of coolant, the electrodes being mutually spaced,
(ii) passing an electrical current across the electrodes whereby to generate an electrical arc therebetween, and
(iii) forming a coating on one of the electrodes which serves as the substrate, said coating being at least partly derived from said coolant.

Preferably, the coolant is liquid nitrogen, the process resulting in a nitrogen-based coating, or the coolant is an organic solvent (e.g. pentane or n-dodecane) or aqueous based resulting in a carbon-based or oxide-based coating. For example, where the substrate is titanium and the coolant is nitrogen, a titanium nitride coating on titanium is formed. When the substrate is tungsten and the coolant is (e.g. pentane or n-dodecane), a tungsten-carbide coating on tungsten is formed.

Preferably, the coating formed in step (iii) is at least 1 μm thick.

In a preferred embodiment, the electrode serving as the substrate (in the form of a rod or sheet) is continuously moved relative to the other electrode, whereby to form a continuous coating on the substrate electrode. Alternatively, the electrode serving as the substrate (which may be a complex 3D shape) is maintained stationary and is surrounded by the other electrode at a given spacing, whereby to provide a continuous coating on the substrate electrode in a single step operation.

It will be understood that the processes of the first and second aspects may be combined into a single process in which a coating is formed on one of the electrodes and a powder is produced from the other electrode.

The present invention also resides in an apparatus for the production of submicron particles and/or for depositing a coating on a substrate, said apparatus comprising:—
(i) a sealable container for coolant,
(ii) an anode and a cathode mounted within the container,
(iii) power supply means for passing a current between the anode and cathode, and
(iv) adjustment means operably connected with at least one of the anode and cathode for controlling the spacing therebetween.

The anode and cathode may have the same or different chemical compositions. Particularly preferred anode/cathode combinations (especially for the production of powders) are:—
graphite-graphite,
graphite-steel,
tungsten-steel,
tungsten-cast iron,
tungsten-aluminium (or aluminium alloy),
tungsten-copper,
tungsten-nickel
tungsten-iron
tungsten-gold
tungsten-titanium,
tungsten-magnesium and
tungsten-stainless steel.

A preferred anode/cathode combination for the production of coatings is tungsten-titanium.

It will be understood that where the anode and cathode have different compositions, the submicron particle powder formed will have the composition of the anode, the cathode, a mixed composition or composite or multilayer composition or will be the product of the reaction between the two electrode materials. The exact composition and structure of the powder depends, inter alia, on the electrode materials, the current density (and hence temperature) of the arc and the melting points or evaporation temperatures or electrical conductivity of the electrodes.

In addition, the anode or cathode may each comprise more than one material, such that, in use, generation of heat by the arc discharge causes the materials to react (solid, molten or vapour phase) before solidification or condensation. Alternatively, the anode and/or cathode may comprise bi-layer or multilayer structures of different materials, such that the layer structures are maintained in the submicron particles formed at the end of the process.

Preferably, a supporting frame is provided for the anode, cathode and adjustment means, which components together with the supporting frame constitute an assembly which is removable from the container.

Preferably, said adjustment means comprises a rod connected to one of the anode and cathode (preferably anode), the rod extending to the anode or cathode through a wall of the container. The rod may be slideably mounted in the wall of the container, but is preferably screw-threadingly engaged therewith and is more preferably controlled by computer and a stepper motor to provide the linear motion of the rod.

In one embodiment, sensing means is provided, the adjustment means and sensing means being operably connected such that in use, the adjustment means is automatically adjusted according to the output of the sensing means.

The sensing means may comprise a voltmeter for monitoring the voltage across the anode and cathode. Alternatively, the sensing means may comprise temperature sensing means to monitor the temperature of the arc. Indirect temperature sensing may be achieved using a spectrometer to monitor the intensity or wavelength of light produced by the arc.

The container may be provided with an inlet and an outlet for coolant. In a preferred arrangement, a coolant return circuit is provided between the outlet and the inlet, in which case the apparatus preferably also comprises a powder recovery region downstream of the container.

Alternatively, the container may be provided with a powder recovery region, such as a collector plate located at the base or on the wall of the container.

It will be understood that the invention also resides in a submicron powder produced according to the method of the first aspect of the invention or using the apparatus of the present invention and to a coated substrate produced according to the method of the second aspect of the invention or using the apparatus of the present invention.

An embodiment of the invention will now be described by way of example only with reference to the accompanying drawings in which

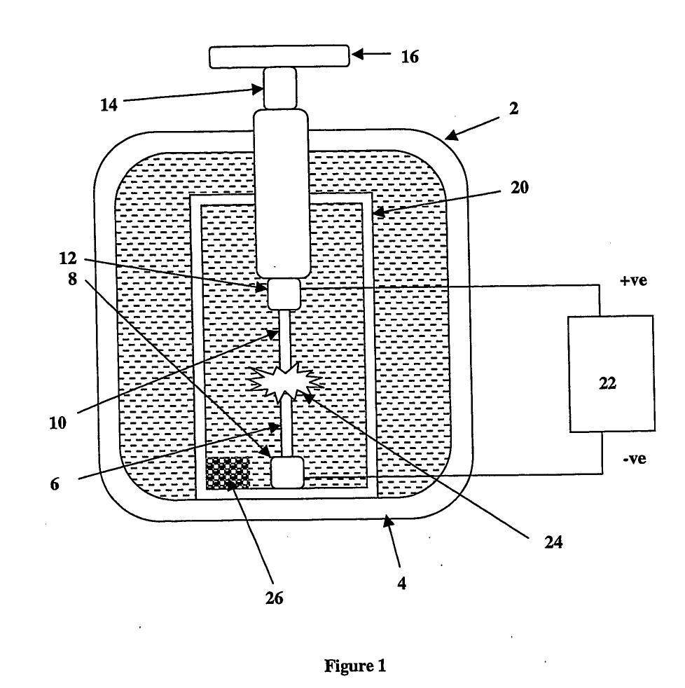

FIG. 1 is a schematic representation of an apparatus in accordance with the invention,

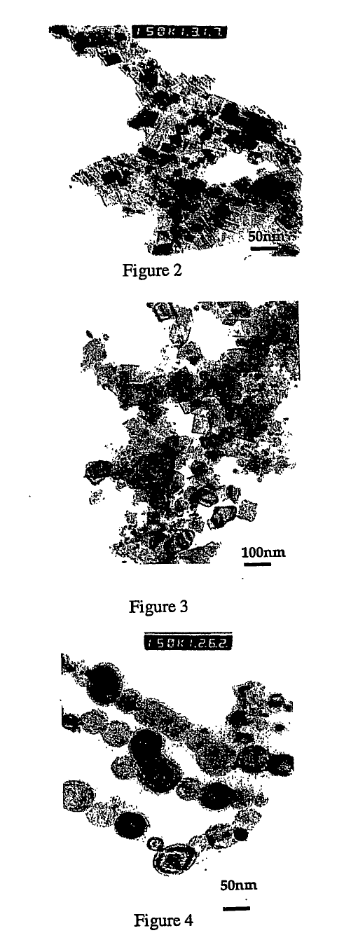

FIGS. 2 to 5 are micrographs of powders produced using the apparatus of FIG. 1, and

FIG. 6 is a micrograph of a coating produced using the apparatus of FIG. 1,

Referring to FIG. 1, a submicron powder producing (and substrate coating) apparatus comprises a sealable container 2 having a thermally insulated wall 4. A first electrode (cathode) 6 in the form of a rod is mounted on a copper block 8 at the base of the container 2 and extends upwardly towards a similarly shaped second electrode (anode) 10. The anode 10 extends downwardly towards the cathode 6 and is also mounted on a copper block 12 which in turn is suspended on a PNFE rod 14 which passes through the top wall of the container 2 and ends in a manually adjustable knob 16. The rod 14 and top wall are provided with cooperating screw threads such that the anode 10 can be raised or lowered by turning the knob 16. The relative positioning of the anode 10 and cathode 6 is stabilised by the provision of a PlFE support frame 20. The anode, 10 the cathode 6, the supporting blocks 8 and 12, the rod 14 and the frame 20 form a sub-assembly which can be raised or lowered out of or into the container as a unit. A dc power supply 22 capable of supplying up to 90A is provided externally of the container 2, and electrical connections are provided to the anode 10 and cathode 6 via the copper blocks 12, 8 to which they are mounted. In an alternative embodiment (not shown), a powder collector plate is provided on the sidewall of the container.

In use, the rod 14 is adjusted so that the anode 10 and the cathode 6 are in contact and the electrode sub-assembly is lowered into the container. The container 2 is then filled with liquid nitrogen and sealed. After thermal equilibration a dc current is applied to the electrodes 6,10 and the knob 16 is turned so as to introduce a gap between the electrodes 6,10 until an electrical discharge arc 24 is induced therebetween. Once the arc 24 is formed, the surface of the anode 10 and/or cathode 6 begins to melt and/or evaporate and fragment into droplets and/or gaseous clusters, which are then quenched and/or condensed into fine (submicron) solid powder particles 26 by the surrounding liquid nitrogen. As a result, the spacing between the anode 10 and the cathode 6 is increased due to removal of material from the anode 10 and/or cathode 6, thereby destabilising the arc 24. In order to stabilise the arc 24 during the continuous production of powders, the anode 10 is lowered by means of the knob 16. This helps to maintain a constant spacing between the anode 10 and the cathode 6, so as to maintain a stable arc 24. After the process has been completed, the worn electrodes 6,10 and PTFE frame 20 are removed from the container 2 leaving the powder-containing liquid nitrogen. This can be poured into a storage container for subsequent use (the powder thereby being protected from air) or the nitrogen can be evaporated to leave free powder.

### EXAMPLE 1

Anode: 6 mm diameter titanium rod

Cathode: 3 mm diameter tungsten rod

Current: 60 A, applied for 40 seconds.

Processing was carried out using the apparatus and method described above to give 1 g of TiN powder. Analysis by transmission electron microscopy (TEM) indicated that the particles had an average size of about 40 nm, the particles being present as agglomerates (FIG. 2).

### EXAMPLE 2

Anode: 6 mm diameter titanium rod

Cathode: 3 mm diameter tungsten rod

Current: 40 A, applied for 40 seconds.

Processing was carried out using the apparatus and method described above to give 1 g of titanium powder. Analysis by transmission electron microscopy (TEM) indicated that the particles had an average size of about 90nm, the particles being present as agglomerates (FIG. 3).

### EXAMPLE 3

Anode: 6 mm diameter iron rod

Cathode: 3 mm diameter tungsten rod

Current: 60 A, applied for 40 seconds

Processing was carried out as for Example 1 to give 1 g of iron powders. Analysis by transmission electron microscopy (TEM) indicated that the particles had an average size of about 60 nm (FIG. 4).

### EXAMPLE 4

Anode: 6 mm diameter aluminium rod

Cathode: 3 mm diameter tungsten rod

Current: 40 A, applied for 30 seconds

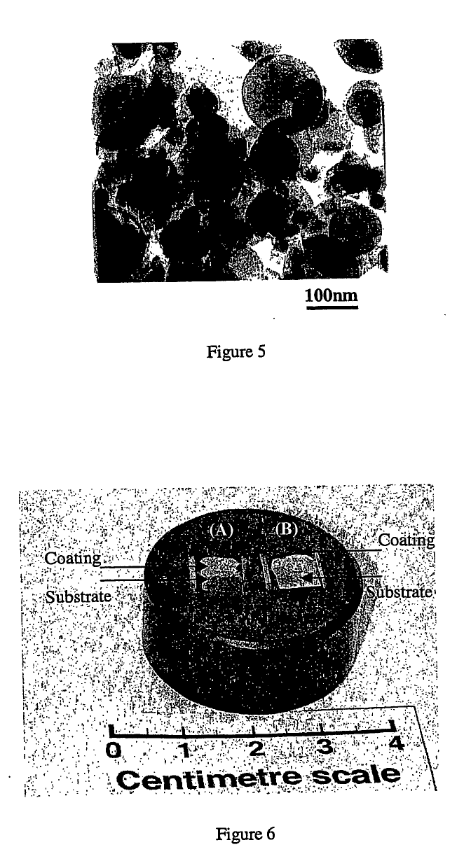

Processing was carried out as for Example 1 to give 3 g of aluminium powder. Analysis by transmission electron microscopy (TEM) indicated that the particles had an average size of about 100 nm (FIG. 5).

### EXAMPLE 5

Anode: 3 mm diameter Fe-2.5% C (grey cast iron) rod

Cathode: 6 mm diameter Fe-2.5% C (grey cast iron) rod

Current: 60 A, applied for 1 second.

Processing was carried out as for Example 1 to give 1 g of cast iron powder. Analysis by scanning electron microscopy (SEM) indicated that about 20% of the particles had a size of less than 1 μm. Substantially all the particles were spherical.

It will be understood that the particle size, size distribution and morphology can be controlled by variation in the current density, the time interval for arc discharge, the geometry and relative positioning of the electrodes, relative motion of the electrodes, electrode materials, temperature and nature of the coolant. For example, only about 20% of the particles were smaller than 1 μm in Example 5. This is due to the relatively low melting point of the cast iron, which results in a larger melt volume at the electrodes which can not be rapidly quenched by the liquid nitrogen. It is anticipated that lowering the current (and therefore temperature) of the arc will reduce the melt volume, increase the rate of quenching and therefore increase the proportion of particles below 1 Jim in diameter.

### EXAMPLES 6A and 6B

Anode: 6 mm Titanium rod

Cathode: 3 mm Tungsten rod

Current: 60A (Example 6A) or 30A (Example 6B), applied for 6 seconds.

Processing was carried out as Example 1 to give a 5 mm thick wear resistance coating of TiN on Ti substrate. Analysis by optical microscope indicated that the coating had excellent adhesion to the substrate (FIG. 6).

In a modification of the above apparatus (not shown), the anode is mounted on a spindle such that it can rotate about its longitudinal axis. This modification enhances the fragmentation of the melt by additional centrifugal force induced by the rotational motion.

In a further modification (not shown) the container is provided with an inlet and an outlet with additional pipe work connecting the two, thereby forming a continuous flow path through the container. A compressor and filtration unit is provided downstream of the outlet. In use, the liquid nitrogen evaporates on leaving the container through the outlet and carries with it the submicron powder. The powder is recovered in the filtration unit and the nitrogen returned to its liquid state by the compressor. This arrangement therefore allows continuous production of the powder until the anode requires replacement.

In yet a further modification, the dc power supply is replaced by an ac power supply. a.c. current causes the electrodes to undergo a cycle of melting/evaporation and freezing/condensation which in turn limits the residence time interval of the melt or vapour phase. This in turn minimizes the volume of melt/vapour near the surface of the electrodes and allows the surrounding liquid nitrogen to quench the small volume of melt/vapour more effectively to produce a fine powder.

It will readily be appreciated that the arc discharge method of the present invention is not particularly limited to any particular technology and can be applied in a diverse range of applications where submicron powders are required. Such applications include solid rocket fuel (eg. Al—Al or Ti—Ti electrodes), catalysts (eg. Ni—Ni electrodes), conducting paste (eg. Cu—Cu electrodes), metallic paints (eg. Al—Al electrodes), hydrogen storage materials (eg. Mg—Mg electrodes), automotive powder metallurgy processed parts (eg. stainless steel-stainless steel electrodes), soft magnetic powder metallurgy processed parts (eg. Fe—Fe electrodes), magnetic targeted carriers (e.g. W—Fe/C bilayer electrodes), thermite welding (eg. Al—Al electrodes), cold-gas spray deposition (eg. tool steel-tool steel electrodes) and dyes. The process is also useful where coating are required, for example wear resistant coatings (TiN, TiC or TiO₂) for engineering components or medical implants.

1-35. (canceled)

36. A process for the production of submicron particles comprising the steps of:—
(i) placing first and second electrodes in a volume of coolant, the electrodes being mutually spaced;
(ii) passing an electrical current across the electrodes whereby to generate an electrical arc therebetween;
(iii) maintaining a stable arc by controlling the relative spacing between the two electrodes to melt or evaporate and separate material from at least one of the electrodes such that droplets of said material are formed; and
(iv) quenching said droplets to form said submicron particles of the material in the coolant.

37. The method of claim 36, wherein the electrodes are initially in contact when the electrical current is passed through them, the arc of step (ii) being created by moving them apart.

38. The method of claim 36, wherein the electrodes used in the method are made from materials selected from metals, metal alloys, graphite carbides, nitrides, oxides, noble metals, amorphous compositions and metal hydrides.

39. The method of claim 38, wherein the metal is selected from one or more of iron, tungsten, aluminum, titanium, magnesium and nickel, the metal alloy is selected from one or more of low carbon steel, cast iron, TiAl, Ti-6Al-4V, stainless steel, tool steel, Fe—Ni—Co—Cr—Mo, Al—Cu—Fe—Mg—Si, Ni—Co—Cr—Fe—W, Cu—Ni, Cu—Sn, Mg—Al—Mn—Si and Co—Cr—Ni—Fe—Mo—W, the carbide is selected from one or more of SiC and WC, the nitride is selected from one or more of TiN, AlN and Si₃N₄, the oxide is selected from one or more of PbTiO₃, TiO₂ and SnO₂, the noble metal is selected from one or more of Au, Pt and Ag, the amorphous composition is selected from one or more of Au—Ge, Co—Fe—B—Si—B—Mo, and Zr—Al—Ni—Cu, and the metal hydride is MgH₂.

40. The method of claim 36, wherein one or both electrodes are bilayer or multi layer.

41. The method of claim 40, wherein each bilayer electrode is made up of an outer layer of graphite and an inner core of Fe or an outer layer of tin or copper and an inner core of aluminum or iron.

42. The method of claim 40, wherein each multilayer electrode is made up of alternate layers of Fe and Cu.

43. The method of claim 36, wherein the coolant is maintained at a temperature of less than 200 K.

44. The method of claim 36, wherein the coolant is liquid nitrogen or liquid argon.

45. The method claim 36, wherein a quantity of reactant is mixed with an essentially inert coolant such that the material melted/evaporated in step (iii) reacts with the reactant prior to being quenched in step (iv).

46. The method of claim 36, wherein a quantity of solvent is introduced into the coolant after step (iv) so as to protect the submicron particles after the removal of the coolant for collection.

47. The method of claim 46, wherein a small quantity of surfactant is introduced into the coolant prior to step (iii) or after the solvent addition to prevent agglomeration of the submicron particles.

48. The method of claim 36, wherein during step (iii), a flow of coolant is introduced into the spacing between the electrodes whereby to displace droplets out of the hot zone of the arc.

49. The method of claim 36, wherein step (iii) is achieved by moving, preferably continuously, one of the electrodes relative to the other as material is melted/evaporated.

50. The method of claim 36, wherein during step (iii), relative rotation is induced between the electrodes whereby to promote separation of the material from the electrode.

51. The method of claim 36, wherein said process is a batch process, the particles being recovered after removal of the coolant.

52. The method of claim 36, wherein the process is continuous, the method including a step of continuously passing coolant over the electrodes.

53. The method of claim 52, wherein the particles are separated from the coolant after passing over the electrodes and the coolant is recycled back over the electrodes in a continuous circuit.

54. A process for depositing a coating on a substrate comprising the steps of:—
(i) placing first and second electrodes in a volume of coolant, the electrodes being mutually spaced;
(ii) passing an electrical current across the electrodes whereby to generate an electrical arc therebetween; and
(iii) forming a coating on one of the electrodes which serves as the substrate, said coating being at least partly derived from said coolant.

55. The method of claim 54, wherein the coolant is liquid nitrogen, an organic solvent or an aqueous based liquid, the process resulting in a nitrogen-based, a carbon-based or oxide-based coating respectfully.

56. The method of claim 54, wherein the coating formed in step (iii) is at least 1 μm thick.

57. The method of claim 54, wherein the electrode serving as the substrate is continuously moved relative to the other electrode, whereby to form a continuous coating on the substrate electrode.

58. The method of claim 54, wherein the electrode serving as the substrate is maintained stationary and is surrounded by the other electrode at a given spacing, whereby to provide a continuous coating on the substrate electrode in a single step operation.

59. An apparatus for the production of submicron particles and/or for depositing a coating on a substrate, said apparatus comprising:—
(i) a sealable container for coolant;
(ii) an anode and a cathode mounted within the container;
(iii) power supply means for passing a current between the anode and cathode; and
(iv) adjustment means operably connected with at least one of the anode and cathode for controlling the spacing therebetween.

60. An apparatus as claimed in claim 59, wherein the anode/cathode combination is selected from graphite-graphite, graphite-steel, tungsten-steel, tungsten-cast iron, tungsten-aluminum or aluminum alloy, tungsten-copper, tungsten-nickel, tungsten-iron, tungsten-gold, tungsten-titanium, tungsten-magnesium and tungsten-stainless steel.

61. The apparatus of claim 59, wherein the anode and/or cathode comprises more than one material, such that, in use, generation of heat by the arc discharge causes the materials to react before solidification or condensation.

62. The apparatus as claimed in claim 61, wherein the anode and/or cathode may comprise bi-layer or multilayer structures of different materials, such that the layer structures are maintained in the submicron particles formed at the end of the process.

63. The apparatus of claim 59, wherein a supporting frame is provided for the anode, cathode and adjustment means, which components together with the supporting frame constitute an assembly which is removable from the container.

64. The apparatus of claim 59, wherein the adjustment means comprises a rod connected to one of the anode and cathode, preferably the anode, the rod extending to the anode or cathode through a wall of the container.

65. The apparatus as claimed in claim 64, wherein the rod is screw-threadingly engaged with the wall of the container.

66. The apparatus of claim 59, wherein sensing means is provided, the adjustment means and sensing means being operably connected such that in use, the adjustment means is automatically adjusted according to the output of the sensing means.

67. The apparatus as claimed in claim 66, wherein the sensing means comprises a voltmeter for monitoring the voltage across the anode and cathode, or temperature sensing means to monitor the temperature of the arc.

68. The apparatus as claimed in claim 67, wherein a spectrometer is used to indirectly measure temperature by monitoring the intensity or wavelength of light produced by the arc.

69. The apparatus of claim 59, wherein the container is provided with an inlet and an outlet for coolant, a coolant return circuit being provided between the outlet and the inlet and a powder recovery region being provided downstream of the container.

70. The apparatus of claim 59, wherein the container is provided with a powder recovery region, such as a collector plate located at the base or on the wall of the container.
